(19) United States
(12) Patent Application Publication
(10) Pub. No.: US 2018/0321344 A1
(43) Pub. Date: Nov. 8, 2018

(54) METHOD, DEVICE AND MAGNETIC RESONANCE APPARATUS FOR TEMPERATURE REGULATION OF A MAGNETIZABLE ENVIRONMENT OF A GRADIENT COIL

(71) Applicant: Siemens Healthcare GmbH, Erlangen (DE)

(72) Inventor: Ralph Kimmlingen, Zirndorf (DE)

(73) Assignee: Siemens Healthcare GmbH, Erlangen (DE)

(21) Appl. No.: 15/971,008

(22) Filed: May 4, 2018

(30) Foreign Application Priority Data
May 4, 2017 (EP) 17169502

(51) Int. Cl. G01R 33/385; G01R 33/38; G01R 33/54

(52) U.S. Cl. CPC G01R 33/3856; G01R 33/543; G01R 33/3804

(57) ABSTRACT

In a method and device for regulating the temperature of the at least partly magnetizable environment of a gradient coil arrangement of a magnetic resonance apparatus, a computer is provided with a first item of information, representing a time-dependent power output of the gradient coil arrangement, and the computer ascertains a prospective temperature of the at least partly magnetizable environment from the first item of information. The computer determines a compensating temperature for a temperature regulating medium based on the ascertained prospective temperature, so that the temperature regulating medium with the compensating temperature produces a temperature in the at least partly magnetizable environment that is stable over time while the time-dependent power output is occurring. The temperature of the at least partly magnetizable environment of the gradient coil arrangement is thereby regulated by producing the compensating temperature in the temperature regulating medium.

### BACKGROUND OF THE INVENTION

### Field of the Invention

The invention concerns a method, a temperature regulating device and a magnetic resonance apparatus for temperature regulation of an at least partly magnetizable environment of a gradient coil.

### Description of the Prior Art

In a magnetic resonance apparatus, the body of an object under examination, in particular a patient, is conventionally exposed to a relatively strong basic magnetic field, for example of 1.5 or 3 or 7 tesla, using a basic field magnet. In addition, gradient pulses are activated with the use of a gradient coil arrangement. Radio-frequency pulses, for example excitation pulses, are then emitted via a radio-frequency antenna by suitable antenna coils, which results in the nuclear spins of specific atoms, which are resonantly excited by these radio-frequency pulses, being tilted by a defined flip angle relative to the magnetic field lines of the basic magnetic field. During relaxation of these nuclear spins, radio-frequency signals known as magnetic resonance signals are emitted, which are received by suitable radio-frequency antennas and then further processed. The desired image data can ultimately be reconstructed from the raw data acquired in this manner.

A specific magnetic resonance control sequence (MR control sequence), also known as a pulse sequence, composed of a succession of radio-frequency pulses, for example excitation pulses and refocusing pulses, together with gradient pulses emitted in a matching, coordinated manner in different gradient axes along different spatial directions, must be emitted for a particular measurement when the magnetic resonance apparatus is in operation. In the process, magnetic field gradients are generated for spatial encoding. Temporally matching read-out windows are set that specify the time intervals in which the induced magnetic resonance signals are acquired.

To generate gradient pulses, currents with amplitudes of up to 1 kA, which are subject to frequent, rapid changes in current direction with rise and fall rates of several 100 T/m/s, are fed into the gradient coils of the gradient coil arrangement. The driving voltage for the coil current can be up to several kV. Due to ohmic losses, eddy-current losses through dynamic stray fields in adjacent conductive structures, and frictional heat resulting from vibration, this leads to heating. Particularly in the case of gradient-intense MR control sequences, such as are used for EPI diffusion, this heating is particularly significant. The gradient coil arrangement typically has a cooling unit that limits the extent of heating during operation of the gradient coil arrangement and/or lowers the temperature of the gradient coil arrangement after completion of the MR control sequence. The heat arising when the gradient coil arrangement is in operation is also dissipated to the environment of the gradient coil arrangement, which is thereby exposed to heating. Cooling of the gradient coil arrangement may likewise bring about a reduction in the temperature of the surroundings of the gradient coil arrangement, but the effect of the cooling on the environment of the gradient coil arrangement is less significant and typically delayed compared to the effect on the gradient coil arrangement itself. Separate cooling may also be provided for the environment of the gradient coil arrangement, which, though typically unable to prevent heating of the environment, is able to cool down the environment rapidly after heating. This results in certain components of the magnetic resonance apparatus in the environment of the gradient coil arrangement being exposed to severe temperature changes, which may affect the durability of these components and/or negatively influence the acquisition of raw data and the quality of the image data to be reconstructed.

### SUMMARY OF THE INVENTION

An object of the present invention is to provide a method for efficient and constant temperature regulation of items that are at least partly magnetizable, which are in the environment of a gradient coil arrangement. It is furthermore an object of the invention to provide a temperature regulating device and a magnetic resonance apparatus that are configured (designed) to implement such a method.

The method according to the invention for regulating the temperature of items that are at least partly magnetizable, which are in the environment of a gradient coil arrangement of a magnetic resonance apparatus, has the following steps.

A first item of information about a time-dependent power output of the gradient coil arrangement is acquired and provided to a computer.

A prospective temperature of the item or items that are at least partly magnetizable in the environment is determined by the computer from the first item of information.

A compensating temperature for a temperature regulating medium is determined by the computer from the ascertained prospective temperature of the at least partly magnetizable item or items in the environment.

The compensating temperature is determined by the computer such that the temperature regulating medium with the compensating temperature produces a temperature for the at least partly magnetizable item or items that is stable over time with the time-dependent power output.

The computer regulates the temperature of the at least partly magnetizable item or items in the environment of the gradient coil arrangement by producing the compensating temperature in the temperature regulating medium.

The gradient coil arrangement is a component of the scanner of the magnetic resonance apparatus, and typically the radio-frequency antenna and the basic field magnet are situated on respective circumferential sides of the gradient coil arrangement. The basic field magnet typically has a cryostat made of metal. Shim elements may be integrated into the gradient coil arrangement. During installation of the magnetic resonance apparatus, a magnetic field of the magnetic resonance apparatus, for example the basic magnetic field or a gradient magnetic field, is typically measured and, on the basis of the measurement results, shim elements, composed of metal, are positioned such that magnetic field inhomogeneity is reduced. These at least partly magnetizable items in the environment of the gradient coil arrangement are characterized by the fact that operation of the gradient coil arrangement leads to heating of such items by power being radiated to the at least partly magnetizable environment during actuation of the gradient coil arrangement. The at least partly magnetizable items are likewise characterized by being magnetizable. Metallic structures are typically exposed to magnetization in the magnetic resonance scanner. Examples of the at least partly magnetizable items in the environment of the gradient coil arrangement are shim elements and the cryostat of the basic field magnet and the radio-frequency antenna.

In summary, the environment of the gradient coil arrangement that is relevant to the present invention is a volume around the gradient coil arrangement that experiences an elevation in temperature due to heat generated during the operation of the gradient coil arrangement, and in which components of the magnetic resonance data acquisition scanner are situated that would be adversely affected in terms of structure or operation or stability by the aforementioned temperature elevation, or by repeated temperature changes implemented to counteract the aforementioned temperature elevation.

Upon actuation of the gradient coil arrangement, gradient pulses are generated, so power is emitted due to high electrical currents and the resistance of the gradient coils. This power output corresponds to the gradient pulses to be activated, which are specified by the MR control sequence that is to be executed by the scanner. The first item of information may be, for example, information about the MR control sequence to be executed or the gradient pulses encompassed by the MR control sequence to be activated. The first item of information may also be a time-dependent power output, which correlates with the MR control sequence to be activated. The time-dependent power output corresponds to the power to be emitted in a time-resolved manner while the MR control sequence is executed. The power to be emitted is typically radiated by the gradient coil arrangement to the environment thereof and/or absorbed by the environment of the gradient coil arrangement.

The prospective temperature indicates how the temperature of the at least partly magnetizable items evolves on the basis of the time-dependent power output and/or will evolve with the time-dependent power output. The prospective temperature typically indicates a change in temperature of the at least partly magnetizable environment on the basis of the time-dependent power output. The prospective temperature may also be expressed as an absolute temperature. The prospective temperature is preferably time-resolved for at least the period during which time-dependent power output proceeds. The first item of information may also be information about a number of MR control sequences to be executed and optionally the order thereof, this being taken into account when ascertaining the prospective temperature. The prospective temperature is typically ascertained on the basis of a calculation and/or an estimate and/or an approximation. The prospective temperature typically indicates a future temperature (prediction) of the at least partly magnetizable environment, which typically cannot be measured and/or experimentally ascertained. The prospective temperature is accordingly typically ascertained without measurement and/or experimental determination.

The temperature regulating medium is typically gaseous or liquid and is conveyed to and/or into the at least partly magnetizable items via a conduit. The temperature regulating medium preferably is water. The conduit is preferably guided to and/or through the at least partly magnetizable items such that the at least partly magnetizable items adopt the temperature of the temperature regulating medium in the conduit as efficiently as possible.

The compensating temperature is characterized as making the temperature of the at least partly magnetizable items constant, as much as possible, i.e. stable over time, during the time-dependent power output and subsequent thereto, while the temperature regulating medium exhibits the compensating temperature. The compensating temperature preferably is a temperature to be achieved and/or set in the temperature regulating medium. The compensating temperature is preferably time-dependent, and is thus preferably determined in a time-resolved manner for a defined period. The temperature regulating medium may be adjusted to the compensating temperature by heating and/or cooling.

An advantage of the method according to the invention is that the at least partly magnetizable items in the environment of the gradient coil arrangement are exposed to the smallest possible temperature change. Due to the predictive determination of the prospective temperature, the at least partly magnetizable items may be particularly well and efficiently regulated to a constant temperature. Since a change in the temperature of the at least partly magnetizable environment may have a negative influence on the acquisition of raw data and the quality of the image data to be reconstructed, the quality of the image data may be improved by the method according to the invention. Due to the continuous temperature regulation, heating maxima may be attenuated and/or interruptions in the cooling of the at least partly magnetizable items may be avoided. In this way, a number of MR control sequences may be executed in quicker succession, such that the duration of the examination of the subject may be shortened. In particular, the order of the MR control sequences to be executed may also be selected as desired. Preferably, the strength of the gradient pulses and/or the sensitivity of an MR control sequence to a change in fundamental frequency need not be taken into account when selecting the order of the MR control sequences to be executed.

A further advantage is based on the relationship between the temperature of the at least partly magnetizable items and the influence thereof on the basic magnetic field. It has been recognized that a change in the temperature of the at least partly magnetizable items influences the magnetization thereof. In particular, the magnetization of a shim element influences the homogeneity and/or the strength of the basic magnetic field. Consequently, a change in the temperature of the at least partly magnetizable environment may change the basic magnetic field and/or a magnetic field gradient, in general a magnetic field generated by the magnetic resonance scanner. A changed magnetic field is typically non-homogeneous, i.e. has local differences. In the case of the basic magnetic field, average strength within a volume may change. The average strength of the basic magnetic field within the central examination volume of the magnetic resonance device may also be expressed as the fundamental frequency. The fundamental frequency corresponds to the Larmor frequency of the hydrogen protons on the basis of the average strength of the basic magnetic field within the central examination volume.

Regardless of the MR control sequence to be executed and/or regardless of the time-dependent power output of the gradient coil arrangement, the method according to the invention allows a largely constant temperature of the at least partly magnetizable items. In the process, the fundamental frequency of the magnetic resonance scanner is kept constant regardless of the MR control sequence to be executed and/or regardless of the time-dependent power output of the gradient coil arrangement.

Spectroscopic MR control sequences are particularly sensitive to changes over time in the fundamental frequency and/or to higher order changes in the basic magnetic field. If the method according to the invention is applied, a spectroscopic MR control sequence may also directly follow a gradient-intense MR control sequence, such as EPI diffusion, without the recording of raw data and the quality of the image data to be reconstructed being negatively influenced. According to the method according to the invention, a change in the fundamental frequency may be minimized regardless of the MR control sequence to be executed. The change in fundamental frequency may in this case be reduced by 80% to 90%.

In an embodiment of the method, a second item of information is the temperature of the at least partly magnetizable items, and is acquired, and this second item of information is taken into account when determining the compensating temperature. If the temperature of the at least partly magnetizable items is known before the start of time-dependent power output, this may also be taken into account when ascertaining the prospective temperature. The prospective temperature thus may be ascertained precisely, so the compensating temperature may also be determined precisely. The temperature of the at least partly magnetizable items thus may be efficiently regulated.

In another embodiment of the method a third item of information is the temperature of the temperature regulating medium and is acquired, and this third item of information is taken into account when producing the compensating temperature in the temperature regulating medium. The compensating temperature may in this way be precisely produced, since the difference between the temperature of the temperature regulating medium and the compensating temperature may be determined and the temperature regulating medium may be cooled or heated by the difference.

When determining the compensating temperature, account is preferably taken of the dependency of a temperature of the at least partly magnetizable items on the temperature of the temperature regulating medium. An item of information representing this dependency is preferably acquired in the context of this embodiment of the method according to the invention, and/or is provided to the computer. The effect of the temperature regulating medium on the at least partly magnetizable items may thereby be taken into account and the compensating temperature precisely determined.

In another embodiment of the method, a fourth item of information is the dependency of a temperature of the at least partly magnetizable items on the time-dependent power output, and is acquired and this fourth item of information is taken into account when ascertaining the prospective temperature of the at least partly magnetizable environment. The dependency may be indicated using a general algorithm, which links a change in the temperature of the at least partly magnetizable environment to a gradient pulse and/or a property of a gradient pulse. The dependency may also be provided specifically for the MR control sequence to be executed. According to this embodiment, the effect of the time-dependent power output on the at least partly magnetizable environment may be taken into account and the compensating temperature determined precisely.

In another embodiment of the method, the fourth item of information is a temperature constant of the at least partly magnetizable environment. A temperature constant quantifies the duration of a change in temperature of the at least partly magnetizable environment, for example depending on the temperature of the surroundings thereof, i.e. on the temperature of the temperature regulating medium. If the temperature constant is taken into account when ascertaining the prospective temperature and/or when determining a compensating temperature, the prospective temperature and/or the compensating temperature may be determined in a precise manner. A constant temperature of the at least partly magnetizable items thus may be ensured over a period, which period may also exceed the duration of the time-dependent power output of the gradient coil arrangement and/or the duration of the MR control sequence.

In another embodiment of the method, the first item of information is a property relating to the type of time-dependent power output. The time-dependent power output is caused by activity of the gradient coil arrangement that activates gradient pulses. The property relating to the type of time-dependent power output may be, for example, the shape of the envelope of the gradient pulses and/or the number thereof and/or density over time thereof. In this way, frequency-dependent effects, such as eddy currents due to stray fields of the gradient coil arrangements, may be taken into account by suitable model parameters. The compensating temperature may thus be precisely determined.

In another embodiment of the method, ascertaining the prospective temperature of the at least partly magnetizable environment includes low-pass filtering of the time-dependent power output. Low-pass filtering of the time-dependent power output corresponds to averaging over time of the time-dependent power output, wherein, for example, the average time-dependent power output for a period of 1 s or of 10 s is stated. After low-pass filtering, the time-dependent power output typically does not relate to individual pulses, but rather is preferably present in the time resolution with which time resolution the compensating temperature is determined and produced. Low-pass filtering brings about a time resolution which is realistic for the further procedure, whereby the compensating temperature may be particularly efficiently determined over an extended period.

In another embodiment of the method, magnetization of the at least partly magnetizable items in the environment of the gradient coil arrangement is stabilized by the temperature regulation. The magnetization of a magnetizable material is typically temperature-dependent, such that a temperature which is constant over time leads, due to temperature regulation, to magnetization of the magnetizable material which is constant over time. If the at least partly magnetizable items are accordingly regulated to a constant temperature, the magnetization thereof and thus also a magnetic field proceeding therefrom is constant. This is particularly relevant in MR imaging, since magnetic fields that change in an uncontrolled manner have a negative influence on the quality of the image data.

In another embodiment of the method, the basic magnetic field of the magnetic resonance scanner that includes the gradient coil arrangement and a basic field magnet that generates the basic magnetic field is stabilized by the temperature regulation, i.e. is kept largely constant and/or unchanged. If the basic magnetic field is stabilized, it displays high homogeneity that is constant over time and a fundamental frequency that is constant over time. This is particularly advantageous in MR imaging, since it is possible to avoid shim drift and/or eliminate shading in resultant image data due to a non-homogeneous basic magnetic field.

In another embodiment of the method, the compensating temperature is determined in a time-dependent manner. One embodiment of the method provides that production of the compensating temperature in the temperature regulating medium proceeds in a time-dependent manner.

The invention also encompasses a temperature regulating device having a temperature regulating medium, a temperature controller and a computer designed to implement the method as described above for regulating the temperature of at least partly magnetizable items in the environment of a gradient coil arrangement of a magnetic resonance scanner. The computer is configured to determine the compensating temperature in the temperature regulating medium and the temperature controller unit is configured to produce the compensating temperature in the temperature regulating medium.

To this end, the computer has an input, a processor, and an output, The computer is provided via the input with the first item of information and/or the second item of information and/or the third item of information and/or the fourth item of information and/or an algorithm for ascertaining the prospective temperature and/or an algorithm for determining a compensating temperature. Further functions, algorithms or parameters required in the method may be provided to the computer via the input. The compensating temperature and/or further results of one embodiment of the method according to the invention are provided via the output. The computer is connected with the temperature controller via the output so that the temperature controller is actuated so as to produce the compensating temperature in the temperature regulating medium.

The temperature controller is configured to cool and/or warm the temperature regulating medium. To this end, the temperature controller is a heat exchanger or a heating element. Further forms of the temperature controller for cooling and/or heating the temperature regulating medium that appear appropriate to those skilled in the art are also conceivable.

The temperature regulating device according to the invention may be retrofitted to magnetic resonance apparatuses already in operation and/or be integrated therein.

In an embodiment of the temperature regulating device, the temperature regulating device has a first sensor connected to the computer that is configured to acquire the first item of information. The first sensor is accordingly configured to acquire the time-dependent power output of the gradient coil arrangement. The time-dependent power output may accordingly be acquired when the gradient coil arrangement is in operation and provided to the computer. The first item of information acquired in this way may serve as a control for a first item of information acquired before operation of the gradient coil arrangement starts, such that the effect of the already determined compensating temperature may be monitored and the compensating temperature may optionally be determined when the method according to the invention is performed again.

The first item of information acquired in this way can likewise be used as the basis for ascertaining the prospective temperature, wherein a temperature constant of the at least partly magnetizable environment is preferably taken into account. The first item of information acquired in this manner typically reflects a change in the temperature of the at least partly magnetizable environment which has already occurred due to activity of the gradient coil arrangement, whereupon the prospective temperature and the compensating temperature are ascertained so that the temperature of the at least partly magnetizable environment remains constant during ongoing activity of the gradient coil arrangement. The time-dependent power output due to the activity of the gradient coil arrangement may in this case be ascertained only retrospectively, such that the method according to the invention is reactive.

An advantage of this embodiment of the temperature regulating device is that it enables temperature regulation of the at least partly magnetizable items even if the time-dependent power output of the gradient coil arrangement is previously unknown, for example in the context of an MR control sequence, in particular prior to the start of the MR control sequence.

In another embodiment of the temperature regulating device the computer is configured to acquire the first item of information on the basis of virtual actuation of the gradient coil arrangement. According to this embodiment, the computer provides an item of information about the gradient pulses of the MR control sequence preferably prior to the start of the MR control sequence. The computer is configured to calculate the time-dependent power output of the gradient coil arrangement associated with the gradient pulses on the basis of the item of information about the gradient pulses. To this end, according to this embodiment virtual actuation of the gradient coil arrangement proceeds according to the MR control sequence, wherein the first item of information is ascertained.

This embodiment of the temperature regulating device enables particularly precise determination of the time-dependent power output to be expected when the MR control sequence is playing out. This embodiment enables determination of the first item of information prior to the start of actuation of the gradient coil arrangement.

In another embodiment of the temperature regulating device, it has a second sensor connected to the computer and configured to acquire a temperature of the at least partly magnetizable items.

In another embodiment, the temperature regulating device has a third sensor connected to the computer and configured to acquire the temperature of the temperature regulating medium.

In another embodiment of the temperature regulating device, the temperature controller has a valve controller. The valve controller is configured to control the flow of the temperature regulating medium. If the temperature regulating device has, for example, a heating element and a cooling element, the valve controller may be configured, as a function of the temperature of the temperature regulating medium and as a function of the compensating temperature, to guide the temperature regulating medium at least in part to the cooling element and/or to the heating element and/or directly into the at least in part magnetizable item. In this way, temperature regulation may proceed in a particularly energy-efficient manner.

In another embodiment of the temperature regulating device, the temperature controller has an input, via which the temperature controller is provided with a designation of the dependency of the temperature of the at least partly magnetizable items on the temperature of the temperature regulating medium.

Further embodiments of the temperature regulating device according to the invention are configured similarly to the embodiments of the method according to the invention as described above. The temperature regulating device may have further control components which are necessary and/or advantageous for carrying out the method according to the invention. The temperature regulating device may also be configured to transmit control signals and/or to receive and/or process control signals, so as to carry out the method according to the invention. Computer programs and further software by which the processor of the computer automatically controls and/or performs a procedure of the method according to the invention may be stored in a memory of the computer.

Furthermore, the invention encompasses a magnetic resonance apparatus having a control computer, a scanner with a gradient coil arrangement with at least one partly magnetizable item in the environment of the gradient coil arrangement, and a temperature regulating device. The temperature regulating device has a temperature regulating medium, a temperature controller and a computer designed to carry out the method according to the invention for temperature regulation of the at least partly magnetizable items in the environment of the gradient coil arrangement. The temperature regulating device may be integrated into the magnetic resonance apparatus. The temperature regulating device may also be installed separately from the magnetic resonance apparatus. The temperature regulating device may be connected to the magnetic resonance apparatus.

In an embodiment of the magnetic resonance apparatus, power output to the at least partly magnetizable item occurs during actuation of the gradient coil arrangement. The gradient coil arrangement is actuated according to the MR control sequence during operation of the scanner of the magnetic resonance apparatus, i.e. when an MR control sequence is executed, such that power output to the at least partly magnetizable item occurs when the scanner is in operation. The method according to the invention for regulating the temperature of at least partly magnetizable environment of the gradient coil arrangement of the magnetic resonance apparatus is carried out at least in part in the context of operation of the magnetic resonance apparatus itself. Temperature regulation is preferably carried out in a time-dependent manner, wherein acquisition of the first item of information and/or ascertainment of the prospective temperature proceeds at least in part prior to the start of the MR control sequence, i.e. prior to the start of actuation of the gradient coil unit.

The advantages of the magnetic resonance apparatus according to the invention and the temperature regulating device according to the invention correspond substantially to the advantages of the method according to the invention for temperature regulation of the at least partly magnetizable items in the environment of the gradient coil arrangement of the magnetic resonance apparatus, which have been explained in detail above. Features, advantages and alternative embodiments mentioned in this connection are likewise also applicable to the other aspects of the invention.

### BRIEF DESCRIPTION OF THE DRAWINGS

FIG. 1 schematically illustrates a first embodiment of the temperature regulating device according to the invention.

FIG. 2 schematically illustrates a second embodiment of the temperature regulating device according to the invention.

FIG. 3 schematically illustrates a third embodiment of the temperature regulating device according to the invention.

FIG. 4 schematically illustrates a magnetic resonance apparatus according to the invention.

FIG. 5 is a flowchart of an embodiment of the method according to the invention.

FIG. 6 shows a time-dependent fundamental frequency without application of the method according to the invention.

FIG. 7 shows a time-dependent fundamental frequency with application of the method according to the invention.

### DESCRIPTION OF THE PREFERRED EMBODIMENTS

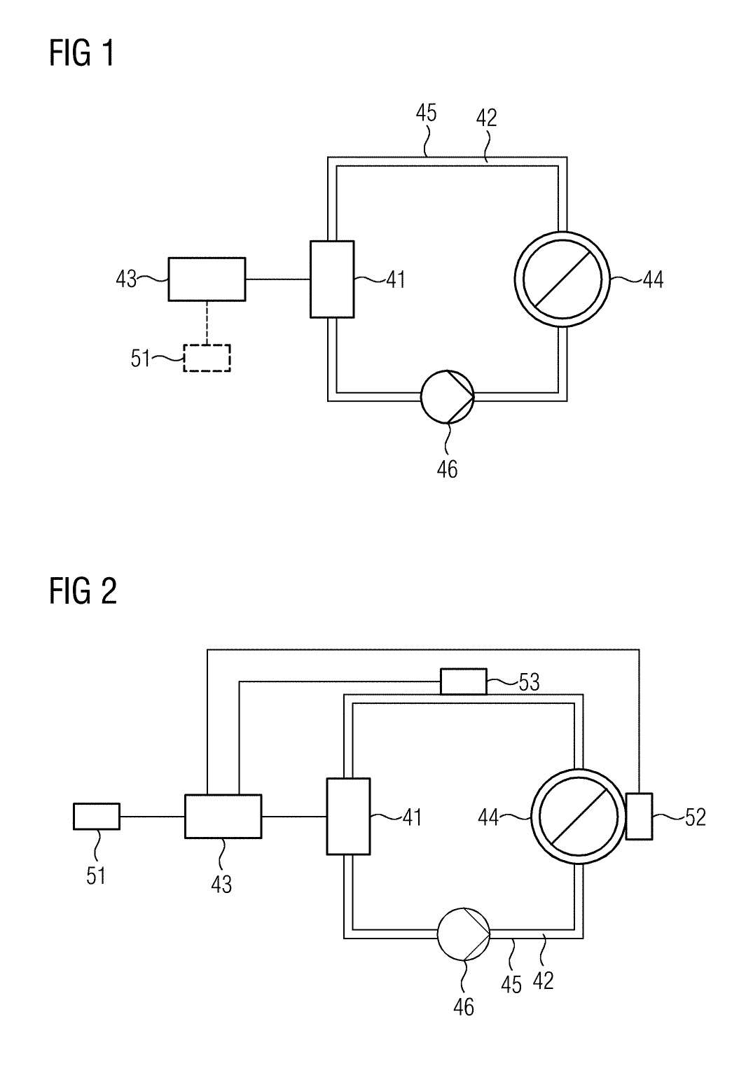

FIG. 1 schematically shows a first embodiment of the temperature regulating device according to the invention. The temperature regulating device is designed to regulate the temperature of at least partly magnetizable item in the environment 44 of a gradient coil arrangement 19 of a scanner of a magnetic resonance apparatus 11. To this end, the temperature regulating device has a temperature regulating medium 42, a temperature controller 41, and a computer 43. The temperature regulating medium 42 is enclosed by a conduit 45 such that the temperature regulating medium 42 is guided in a directional manner in the conduit 45. The conduit 45 may to this end have a temperature regulating medium directing member 46, which causes directional flow of the temperature regulating medium 42 from the temperature controller 41 to the at least partly magnetizable environment 44.

The conduit 45 is preferably designed so as to be guided to the at least partly magnetizable environment 44 and/or therethrough. The at least partly magnetizable environment 44 is here depicted as a thermal load.

The computer 43 is configured to determine a compensating temperature in the temperature regulating medium 42. To this end, the computer 43 ascertains a prospective temperature of the at least partly magnetizable environment 44 on the basis of a first item of information about a time-dependent power output of the gradient coil arrangement 19. The computer 43 may be configured to acquire the first item of information on the basis of virtual actuation of the gradient coil arrangement 19. In this respect, the computer 43 has an input, via which an item of information relating to an MR control sequence to be executed is provided to the computer 43. The computer 43 is in this case preferably connected to the control computer 24 of the magnetic resonance apparatus 11. The computer 43 may have a memory in which an item of information about the time-dependent power output of the MR control sequence to be executed is stored.

The temperature regulating device may optionally have a first sensor 51. The first sensor 51 is connected to the computer 43 and is configured to acquire the first item of information and to provide it to the computer 43. The first sensor 51 is typically on the gradient coil arrangement 19 and/or on an electrical feed line of the gradient coil arrangement 19. The temperature controller 41 is configured to produce the compensating temperature in the temperature regulating medium 42.

FIG. 2 shows a second embodiment of the temperature regulating device according to the invention. In addition to the first embodiment of the temperature regulating device, the temperature regulating device of FIG. 2 has a second sensor 52 and a third sensor 53. The two sensors 52, 53 may also be used individually or independently.

The second sensor 52 is connected to the computer 43 and is configured to acquire a temperature of the at least partly magnetizable environment 44. To this end, the second sensor 52 is arranged on or in the at least partly magnetizable environment 44. The third sensor 53 is connected to the computer 43 and is configured to acquire the temperature of the temperature regulating medium 42. To this end, the third sensor 53 is arranged on the conduit 45 or in the temperature regulating medium 42.

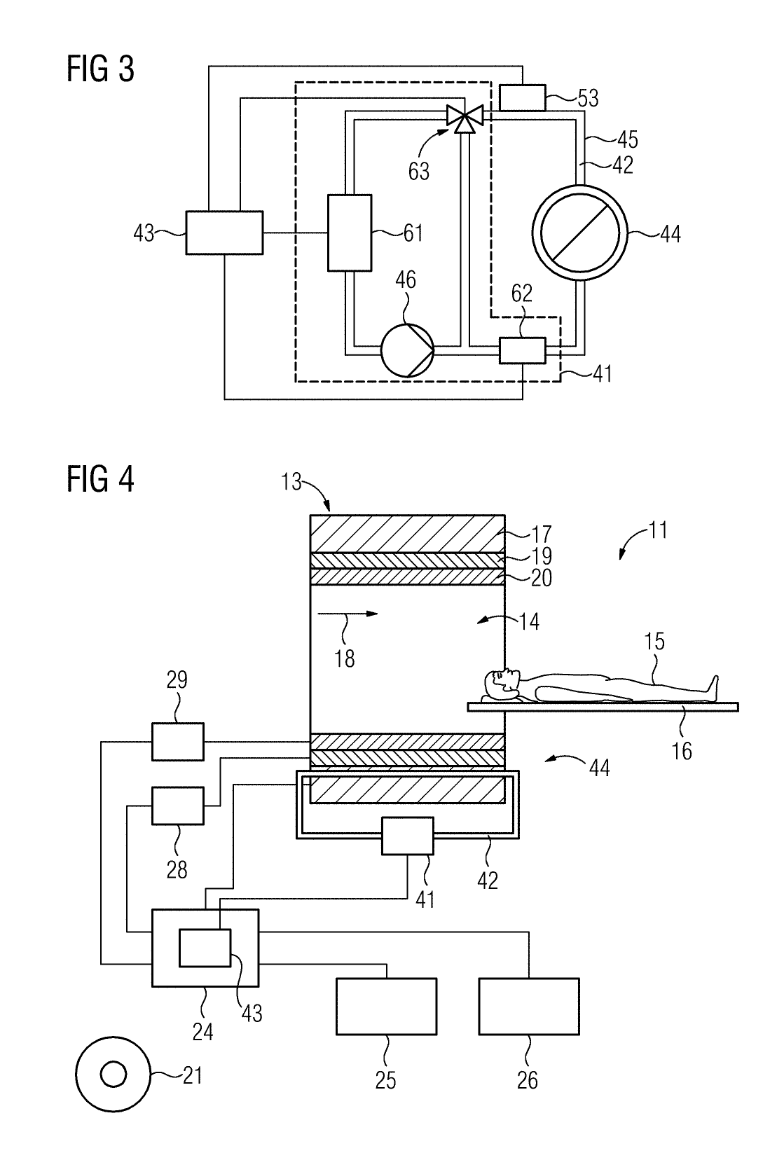

FIG. 3 illustrates a third embodiment of the temperature regulating device according to the invention, wherein a specific embodiment of the temperature controller 41, having a valve controller 63, is shown. The temperature controller 41 in this embodiment includes the valve controller 63, a heat exchanger 61, and a heating element 62. The computer 43 is connected to the valve controller 63, the heat exchanger 61 and the heating element 62 so as to be able to actuate those components. The third sensor 53 is arranged on the return conduit, such that the third sensor acquires the temperature of the temperature regulating medium 42 after passage thereof through the at least partly magnetizable environment 44. The computer 43 compares the temperature of the temperature regulating medium 42 ascertained by the third sensor 53 with the compensating temperature ascertained by the computer 43. The computer 43 is provided with algorithms that allows it to control the heat exchanger 61 so as to cool the temperature regulating medium 42 and/or to control the heating element 62 to heat the temperature regulating medium 42 and/or to control the valve controller 63 such that the compensating temperature in the temperature regulating medium 42 is achieved in the most energy-efficient manner possible in the region of the at least partly magnetizable environment 44. The valve controller 63 is configured to subdivide the temperature regulating medium 42 into a first sub-quantity and into a second sub-quantity, such that the first sub-quantity of the temperature regulating medium 42 is fed through the heating element 62 or past the heating element 62 to the at least partly magnetizable environment 44 and the second sub-quantity is initially fed to the heat exchanger 61.

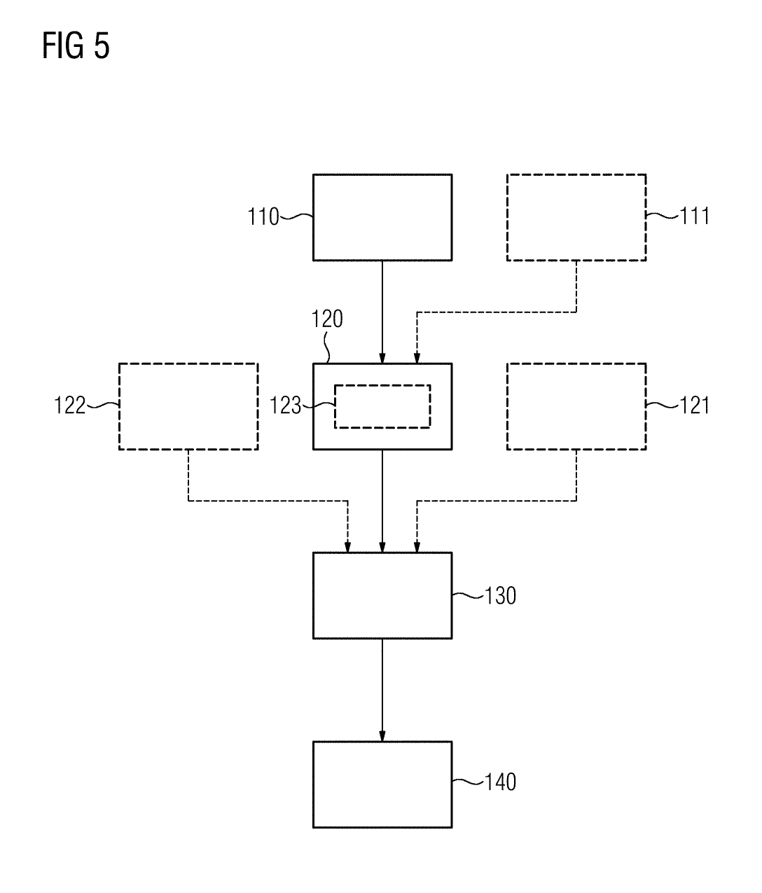

FIG. 4 schematically illustrates a magnetic resonance apparatus 11 according to the invention. The magnetic resonance apparatus 11 that an MR data acquisition scanner 13 with a basic field magnet 17 that generates a strong and constant basic magnetic field 18. The scanner 13 has a cylindrical patient accommodation zone 14 for receiving a patient 15, wherein the patient accommodation zone 14 is cylindrically enclosed at its circumference by the scanner 13. The patient 15 can be advanced into the patient accommodation zone 14 by a patient positioning apparatus 16 of the magnetic resonance apparatus 11.

The scanner 13 further has a gradient coil arrangement 19, which is used for spatially encoding MR signals during data acquisition. The gradient coil arrangement 19 is actuated by a gradient controller 28. The scanner 13 further has a radio-frequency antenna 20, which in the case shown is a body coil fixedly integrated into the scanner 13. The radio-frequency antenna 20 is actuated by a radio-frequency antenna controller 29 so as to emit radio-frequency pulses into an examination chamber, which is substantially formed by the patient accommodation zone 14. The emitted radio-frequency pulses cause certain nuclear spins in the patient 15 to be deflected from the field lines of the basic magnetic field 18 by a defined amount, known as a flip angle. As these excited nuclear spins relax and return to the steady state, they emit the aforementioned MR signals, which are detected by the same RF antenna from which the RF pulses were radiated, or by a different RF reception antenna.

In the environment of the gradient coil arrangement 19, magnetizable components are situated, such as the basic field magnet 17 and the radio-frequency antenna 20 and/or further parts of the scanner 13, which form the at least partly magnetizable environment 44 of the gradient coil arrangement 19. The at least partly magnetizable environment 44 of the gradient coil arrangement 19 may likewise include a shim element in a region formed by the gradient coil arrangement 19 and/or the basic field magnet 17 and/or by the radio-frequency antenna 20.

The magnetic resonance apparatus 11 has a control computer 24 that controls the basic field magnet 17, the gradient controller 28 and the radio-frequency antenna controller 29. The control computer 24 centrally controls the magnetic resonance apparatus 11 for the performance of MR control sequences. The magnetic resonance apparatus 11 has a display unit 25. Control information such as control parameters, and reconstructed image data, may be displayed for a user on the display unit 25, for example on at least one monitor. The magnetic resonance apparatus 11 furthermore has an input unit 26, via which information and/or control parameters may be entered by a user during a measurement procedure. The control computer 24 may include the gradient controller 28 and/or the radio-frequency antenna controller 29 and/or the display unit 25 and/or the input unit 26.

The magnetic resonance apparatus 11 further has a computer 43, a temperature controller 41 and a temperature regulating medium 42. The computer 43, the temperature controller 41 and the temperature regulating medium 42 together form a temperature regulating device according to the invention. In this respect, the computer 43 is connected to the control computer 24 or integrated therein. The computer 43 is additionally connected to the temperature controller 41.

The computer 43 is configured to determine the compensating temperature in the temperature regulating medium 42. The temperature controller 41 is configured to produce the compensating temperature in the temperature regulating medium 42. To this end, the computer 43 has computer programs and/or software that can be loaded directly into a memory of the computer 43, with program code for carrying out the method for regulating the temperature of the at least partly magnetizable environment 44 of the gradient coil arrangement 19 when the computer programs and/or software are executed in the computer 43. To this end, the computer 43 has a processor (not separately shown) designed to carry out the method of the computer programs and/or software. Alternatively, the computer programs and/or software may be stored on an electronically readable data storage medium 21 that is separate from the control computer 24 and/or computer 43. The electronically readable data storage medium 21 can be loaded into the control computer 24 and/or the computer 43.

The illustrated magnetic resonance apparatus 11 may of course have further components that are common to magnetic resonance apparatuses in general. The basic manner of operation of the magnetic resonance apparatus 11 for MR data acquisition is known to those skilled in the art, and therefore need not be described in further detail herein.

FIG. 5 is a flowchart of an embodiment of the method according to the invention for regulating the temperature of an at least partly magnetizable environment 44 of a gradient coil arrangement 19 of a magnetic resonance apparatus 11. In this case, a first item of information about a time-dependent power output of the gradient coil arrangement 19 is acquired in method step 110. In method step 110, for example, the time profile of the input of power or heat resulting from operation of the gradient coil arrangement 19, i.e. resulting from actuation of the gradient coil arrangement 19 according to the preset values of an MR control sequence, are calculated prior to start of the MR control sequence and/or are measured while the MR control sequence is being executed, i.e. during operation of the gradient coil arrangement 19. The first item of information may be a characteristic relating to the type of time-dependent power output. This may be, for example, frequency-dependent effects such as eddy-current effects generated by stray fields of the magnetic field gradients generated by the gradient coil arrangement 19.

On the basis of the first item of information, a prospective temperature of the at least partly magnetizable environment 44 is ascertained in method step 120. A characteristic represented by the first item of information may then be taken into account by suitable model parameters. Method step 120 may optionally include method step 123, which is low-pass filtering of the time-dependent power output. Parameters for the low-pass filtering may be determined, for example, by a one-time calibration measurement in the context of the method according to the invention and/or provided to the method according to the invention by storing the parameters in a memory. In this way, account is taken of the fact that, due to thermal resistances and/or capacitances of the at least partly magnetizable environment 44, a time delay may occur between the time-dependent power output and a change in temperature and/or a change in the magnetization of the at least partly magnetizable environment 44.

On the basis of the prospective temperature ascertained in method step 120, method step 130 determines a compensating temperature of the temperature regulating medium 42 such that, in view of the time-dependent power output, the temperature regulating medium 42 is provided with the compensating temperature so as to then have a temperature that is stable over time for the at least partly magnetizable environment 44. Finally, in method step 140, temperature regulation of the at least partly magnetizable environment 44 of the gradient coil arrangement 19 proceeds through production of the compensating temperature in the temperature regulating medium 42. For production of the compensating temperature in the temperature regulating medium 42, the temperature of the temperature regulating medium 42 in the feed to the gradient coil arrangement 19 is known, such that the compensating temperature in the temperature regulating medium 42 can be established by a cooling element and/or by a heating element. The temperature of the temperature regulating medium 42 in the feed to the gradient coil arrangement 19 may be determined by a calibration measurement, for example by executing an MR control sequence with an average time-dependent power output. In this way, magnetization of the at least partly magnetizable environment 44 of the gradient coil arrangement 19 may be stabilized, so the basic magnetic field 18 of the scanner 13 is preferably also stabilized.

In method step 111, a fourth item of information designating the dependency of the temperature of the at least partly magnetizable environment 44 on the temperature of the temperature regulating medium 42 is optionally acquired. This fourth item of information is then taken into account in method step 120 when ascertaining the prospective temperature of the at least partly magnetizable environment 44. The fourth item of information may in this case be a time constant associated with temperature change in the at least partly magnetizable environment 44. In method step 121, a second item of information designating the temperature of the at least partly magnetizable environment 44 is optionally acquired, and this second item of information is taken into account when determining the compensating temperature in method step 130. In method step 122, a third item of information designating the temperature of the temperature regulating medium 42 may likewise optionally be acquired, with the third item of information being taken into account when producing the compensating temperature in the temperature regulating medium 42.

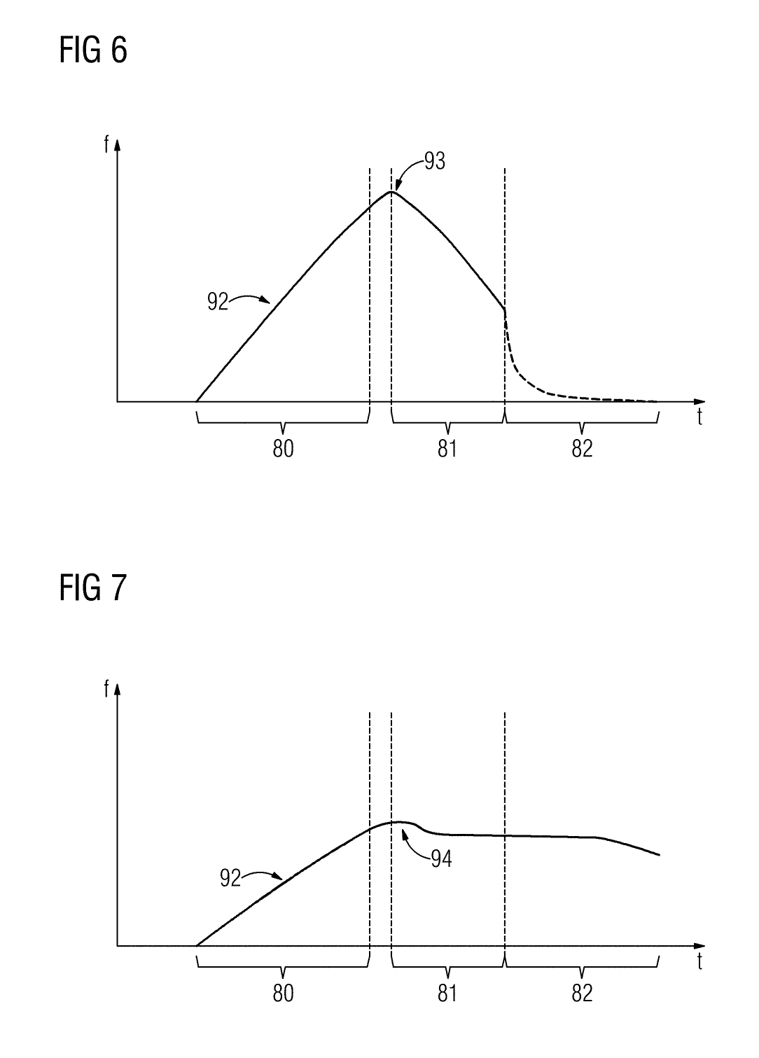

The graph in FIG. 6 shows a first instance of a time-dependent fundamental frequency f of the scanner 13 without application of the method according to the invention, and the diagram in FIG. 7 shows a second instance of a time-dependent fundamental frequency f with application of the method according to the invention. The cause of the change in the fundamental frequency f is identical activity of the gradient coil arrangement 19 in the first and second instances during the period 80, which leads in each case to a rise 91, 92 in the fundamental frequency f. The rise 91 in the fundamental frequency f in the first instance is greater than the rise 92 in the fundamental frequency f in the second instance, since according to the method according to the invention the compensating temperature is determined in a time-dependent manner and at the start of the period 80 the at least partly magnetizable environment 44 already is or has been preheated, for example, such that heating, and thus an increase in the fundamental frequency f due to the time-dependent power output, is less. At the end of the period 80, the at least partly magnetizable environment 44 initially continues to warm in the first and second cases and, after a time delay, the fundamental frequency f reaches a first maximum 93 in the first case and a second maximum 94 in the second case on the basis of time constants of the at least partly magnetizable environment 44. The timing of the first maximum may differ from the timing of the second maximum.

In the first case, the fundamental frequency f falls more sharply after the first maximum 93 than in the second case after the second maximum 94. In the first case, indirect cooling in the period 81 brings about a reduction in the magnetization of the at least partly magnetizable environment 44, the coolant 42 being guided via a bypass. In the subsequent period 82, the fundamental frequency f falls exponentially due to direct and active cooling. In the second case, the time-dependent compensating temperature is in contrast selected such that the fundamental frequency f remains approximately constant in the periods 81 and 82 after the second maximum 94. An increase in the temperature of the at least partly magnetizable environment 44 may also bring about a reduction in the fundamental frequency f. In this case, the diagrams of FIGS. 6 and 7 would be depicted in a horizontally reflected manner.

Although modifications and changes may be suggested by those skilled in the art, it is the intention of the Applicant to embody within the patent warranted hereon all changes and modifications as reasonably and properly come within the scope of the Applicant's contribution to the art.

1. A method for regulating a temperature of an environment of a gradient coil arrangement of a magnetic resonance scanner, said environment comprising at least one magnetizable component of said scanner, said method comprising:
providing a computer with a first item of information that describes a time-dependent power output of said gradient coil arrangement when said gradient coil arrangement is operational;
in said computer, using said first item of information to determine a prospective temperature of said environment;
in said computer, determining a compensating temperature for a temperature regulating medium based on the ascertained prospective temperature of the environment, which will cause the temperature regulating medium with said compensating temperature to produce a temperature in said environment that is stable over time while said time-dependent power output occurs; and
operating a temperature controller from said computer in order to regulate the temperature in said environment by producing the compensating temperature in the temperature regulating medium.

2. A method as claimed in claim 1 comprising providing said computer with a second item of information representing the temperature of said environment and, in said computer, also using said second item of information when determining said compensating temperature.

3. A method as claimed in claim 2 comprising providing said computer with a third item of information representing a temperature of said temperature regulating medium and, in said computer, also using said third item of information when determining said compensating temperature.

4. A method as claimed in claim 3 comprising providing said computer with a fourth item of information comprising a dependency of the temperature of said environment on the temperature of the temperature regulating medium, and also using said fourth item of information when determining said compensating temperature.

5. A method as claimed in claim 4 wherein said fourth item of information is a time constant associated with temperature change in said environment.

6. A method as claimed in claim 1 wherein said first item of information is a characteristic related to a type of said time-dependent power output.

7. A method as claimed in claim 1 comprising, in said computer, low-pass filtering said time-dependent power output when ascertaining said prospective temperature of said environment.

8. A method as claimed in claim 1 comprising producing said temperature regulation of said environment so as to stabilize a magnetization of said at least one magnetizable component in said environment.

9. A method as claimed in claim 8 wherein said at least one component for which said magnetization is stabilized is selected from the group consisting of a basic field magnet of said scanner.

10. A temperature regulating device for regulating a temperature of an environment of a gradient coil arrangement of a magnetic resonance scanner, said environment comprising at least one magnetizable component of said scanner, said device comprising:
a computer provided with a first item of information that describes a time-dependent power output of said gradient coil arrangement when said gradient coil arrangement is operational;
said computer being configured to use said first item of information to determine a prospective temperature of said environment;
a temperature regulating medium;
said computer being configured to determine a compensating temperature for said temperature regulating medium based on the ascertained prospective temperature of the environment, which will cause the temperature regulating medium with said compensating temperature to produce a temperature in said environment that is stable over time while said time-dependent power output occurs; and
a temperature controller operated from said computer in order to regulate the temperature in said environment by producing the compensating temperature in the temperature regulating medium.

11. A temperature regulating device as claimed in claim 10 comprising a first sensor that acquires said first item of information and provides said first item of information to said computer.

12. A temperature regulating device as claimed in claim 10 wherein said computer is configured to acquire said first item of information by executing a virtual actuation of said gradient coil arrangement.

13. A temperature regulating device as claimed in claim 10 comprising a second sensor that acquires a temperature of said environment and provides a second item of information representing said temperature to said computer.

14. A temperature regulating device as claimed in claim 10 comprising a third sensor that acquires a temperature of the temperature regulating medium as a third item of information, and that provides said third item of information to said computer.

15. A temperature regulating device as claimed in claim 10 wherein said temperature controller comprises a valve controller that controls a flow of said temperature regulating medium in said environment.

16. A magnetic resonance apparatus comprising:
a magnetic resonance data acquisition scanner comprising a gradient coil arrangement that, when operated during acquisition of MR data, generates heat in an environment of the gradient coil arrangement in which components of the MR data acquisition scanner are situated, at least one of said components being magnetizable;
a computer provided with a first item of information that describes a time-dependent power output of said gradient coil arrangement when said gradient coil arrangement is operational;
said computer being configured to use said first item of information to determine a prospective temperature of said environment;
a temperature regulating medium;
said computer being configured to determine a compensating temperature for said temperature regulating medium based on the ascertained prospective temperature of the environment, which will cause the temperature regulating medium with said compensating temperature to produce a temperature in said environment that is stable over time while said time-dependent power output occurs; and
a temperature controller operated from said computer in order to regulate the temperature in said environment by producing the compensating temperature in the temperature regulating medium.
